(19) United States
(12) Patent Application Publication
(10) Pub. No.: US 2012/0153354 A1
(43) Pub. Date: Jun. 21, 2012

(54) PERFORMANCE ENHANCEMENT IN TRANSISTORS COMPRISING HIGH-K METAL GATE STACKS AND AN EMBEDDED STRESSOR BY PERFORMING A SECOND EPITAXY STEP

(75) Inventors: Stephan Kronholz, Dresden (DE); Gunda Beernink, Dresden (DE); Maciej Wiatr, Dresden (DE)

(73) Assignee: GLOBALFOUNDRIES Inc., Grand Cayman (KY)

(21) Appl. No.: 13/236,226

(22) Filed: Sep. 19, 2011

(30) Foreign Application Priority Data
Dec. 21, 2010 (DE) 10 2010 063 782.3

(51) Int. Cl. H01L 29/78; H01L 21/336; H01L 21/8234

(52) U.S. Cl. 257/192; 438/301; 438/289; 438/285; 257/E29.266; 257/E21.409; 257/E21.616

(57) ABSTRACT

When forming sophisticated transistors, for instance comprising high-k metal gate electrode structures, a significant material loss of an embedded strain-inducing semiconductor material may be compensated for, or at least significantly reduced, by performing a second epitaxial growth step after the incorporation of the drain and source extension dopant species. In this manner, superior strain conditions may be achieved, while also the required drain and source dopant profile may be implemented.

### BACKGROUND OF THE INVENTION

1. Field of the Invention

Generally, the present disclosure relates to the fabrication of integrated circuits, and, more particularly, to P-channel transistors comprising a high-k metal gate electrode formed in an early manufacturing stage.

2. Description of the Related Art

The fabrication of complex integrated circuits requires a large number of transistor elements to be formed on a single semiconductor die. For example, several hundred millions of transistors may be provided in presently available complex integrated circuits. Generally, a plurality of process technologies are currently practiced, wherein, for complex circuitry, such as microprocessors, storage chips and the like, CMOS technology is the most promising approach due to the superior characteristics in view of operating speed and/or power consumption and/or cost efficiency. In CMOS circuits, complementary transistors, i.e., P-channel transistors and N-channel transistors, are used for forming circuit elements, such as inverters and other logic gates to design highly complex circuit assemblies, such as CPUs, storage chips and the like. During the fabrication of complex integrated circuits using CMOS technology, millions of transistors, i.e., N-channel transistors and P-channel transistors, are formed on a substrate including a crystalline semiconductor layer. A MOS transistor or generally a field effect transistor, irrespective of whether an N-channel transistor or a P-channel transistor is considered, comprises so-called PN junctions that are formed by an interface of highly doped drain and source regions and a weakly doped channel region disposed between the drain region and the source region. The conductivity of the channel region, i.e., the drive current capability of the conductive channel, is controlled by a gate electrode formed in the vicinity of the channel region and separated therefrom by a thin insulating layer. The conductivity of the channel region, upon formation of a conductive channel due to the application of an appropriate control voltage to the gate electrode, depends on the dopant concentration, the mobility of the charge carriers and, for a given extension of the channel region in the transistor width direction, on the distance between the source and drain regions, which is also referred to as channel length. Thus, the reduction of the channel length, and associated therewith the reduction of the channel resistivity, is a dominant design criterion for accomplishing an increase in the operating speed of the integrated circuits.

The continuing shrinkage of the transistor dimensions, however, involves a plurality of issues associated therewith that have to be addressed so as to not unduly offset the advantages obtained by steadily decreasing the channel length of MOS transistors. For example, highly sophisticated dopant profiles, in the vertical direction as well as in the lateral direction, are required in the drain and source regions so as to provide low sheet and contact resistivity in combination with desired channel controllability.

With a reduced channel length, generally a shallow dopant profile may be required in the drain and source regions, while nevertheless a moderately high dopant concentration is necessary in view of providing a low series resistance, which in turn results in a desired drive current in combination with a reduced transistor channel length. A shallow dopant profile in combination with a low overall drain and source resistance is typically realized by forming so-called drain and source extension regions, which may represent extremely shallow doped areas extending below the gate electrode structure so as to appropriately connect to the channel region. On the other hand, an increased lateral offset from the channel region is adjusted on the basis of appropriately dimensioned sidewall spacers, which are used as implantation masks for forming the actual drain and source regions with a desired high dopant concentration and with an increased depth compared to the drain and source extension regions. By appropriately selecting the size of the drain and source extension regions, channel controllability may be maintained for very short channel transistors, while also providing a desired low overall series resistance in connecting the drain and source regions to the channel region. Consequently, for a desired performance of sophisticated transistor elements, a certain degree of overlap of the drain and source extension regions with the gate electrode is desirable in order to obtain a low threshold voltage and a high current drive capability. The overlap of the drain and source extension regions with the gate electrode gives rise to a specific capacitive coupling that is also referred to as Miller capacitance. Typically, a desired Miller capacitance is adjusted on the basis of implantation processes in which the drain and source dopants may be introduced in order to form the basic configuration of the drain and source extension regions, wherein the final shape of these regions may then be adjusted on the basis of a sequence of anneal processes in which implantation-induced damage is re-crystallized and also a certain degree of dopant diffusion may occur, thereby finally determining the resulting Miller capacitance.

Upon continuously reducing the channel length of field effect transistors, generally an increased degree of capacitive coupling is required in order to maintain controllability of the channel region, which is frequently addressed by adapting a thickness and/or material composition of the gate dielectric material. For example, for a gate length of approximately 80 nm, a gate dielectric material based on silicon dioxide with a thickness of less than 2 nm may be required in high speed transistor elements, which may, however, result in increased leakage currents caused by hot carrier injection and direct tunneling of charge carriers through the extremely thin gate dielectric material. Since a further reduction in thickness of silicon dioxide-based gate dielectric materials may become increasingly incompatible with thermal power requirements of sophisticated integrated circuits, other alternatives have been developed in increasing the charge carrier mobility in the channel region, thereby also enhancing overall performance of field effect transistors. One promising approach in this respect is the generation of a certain type of strain in the channel region, since the charge carrier mobility in silicon strongly depends on the strain conditions of the crystalline material. For example, for a standard crystallographic configuration of the silicon-based channel region, a compressive strain component in a P-channel transistor may result in superior mobility of holes, thereby increasing switching speed and drive current of P-channel transistors. The desired compressive strain component may be obtained according to well-established approaches by incorporating a strain-inducing semiconductor material, for instance in the form of a silicon/germanium mixture or alloy, in the active region of the P-channel transistor. For example, after forming the gate electrode structure, corresponding cavities may be formed laterally adjacent to the gate electrode structure in the active region and may be refilled with the silicon/germanium alloy which, when grown on the silicon material, may have an internal strained state, which in turn may induce a corresponding compressive strain component in the adjacent channel region. Consequently, a plurality of process strategies has been developed in the past in order to incorporate a highly strained silicon/germanium material in the drain and source areas of P-channel transistors.

In addition to the very efficient strain-inducing mechanism based on silicon/germanium for P-channel transistors, other performance enhancing mechanisms have been implemented in the past. For example, in view of the continuous reduction of the critical dimensions of transistors, an appropriate adaptation of the material composition of the gate dielectric material has been proposed such that, for a physically appropriate thickness of a gate dielectric material, i.e., for keeping the resulting gate leakage currents at an acceptable level, a desired high capacitive coupling is achieved. For this reason, material systems have been developed which may a significantly higher dielectric constant compared to the conventionally used silicon dioxide-based materials, such as silicon oxynitride and the like. For example, materials including hafnium, zirconium, aluminum and the like may have a significantly higher dielectric constant when provided as oxides or silicates, wherein these materials are typically referred to as high-k dielectric materials, which are to be understood as materials having a dielectric constant of 10.0 or higher when measured in accordance with typical measurement techniques. As is well known, the electronic characteristics of transistor elements also strongly depend on the work function of the gate electrode material, which influences the band structure of the semiconductor material in the channel region that is separated from the gate electrode material by the gate dielectric layer. In well-established polysilicon/silicon dioxide-based gate electrode structures, the corresponding threshold voltage that is strongly influenced by the gate dielectric material and the adjacent electrode material is adjusted by appropriately doping the polysilicon material in order to adjust the work function of the polysilicon material at the interface between the gate dielectric material and the electrode material. Similarly, in gate electrode structures including a gate insulation layer based on a high-k dielectric material, the work function has to be appropriately adjusted for N-channel transistors and P-channel transistors, respectively, which requires appropriately selected work function adjusting metal species, such as lanthanum for N-channel transistors and aluminum for P-channel transistors. Therefore, corresponding metal-containing conductive materials have to be positioned close to the high-k dielectric material in order to form an appropriately designed interface that results in the target work function of the gate electrode structure. In some conventional approaches, the work function adjustment is accomplished at a very late manufacturing stage, i.e., after any high temperature processes, wherein the replacement of a placeholder material of the gate electrode structures, such as a polysilicon material, and the incorporation of appropriate work function adjusting species in combination with an electrode metal is required in this very advanced manufacturing stage. Consequently, very complex patterning and deposition process sequences have to be applied in the context of gate electrode structures having critical dimensions of 50 nm and less, which may finally result in severe variations of the resulting transistor characteristics.

In other process strategies, the work function adjusting materials are applied in an early manufacturing stage, i.e., upon forming the gate electrode structures, wherein the corresponding metal species may be thermally stabilized and encapsulated in order to preserve the work function and thus threshold voltage of the transistors without undue influence by the further processing. For this purpose, in some cases, P-channel transistors may require an appropriate adaptation of the band gap of the semiconductor material in the channel region in order to appropriately set the work function of the P-channel transistors and thus the threshold voltages thereof with respect to the N-channel transistors. For this reason, frequently a so-called threshold adjusting semiconductor alloy, for instance in the form of a silicon/germanium alloy, is formed on the active regions of the P-channel transistors prior to forming the gate electrode structures. Although the approach of providing the sophisticated high-k metal gate electrode structures in an early manufacturing stage and preserving the electronic characteristics thereof by appropriately encapsulating and thus passivating the gate electrode structures, nevertheless also a plurality of additional process steps may be required, in particular in combination with the incorporation of a strain-inducing semiconductor alloy in the active region of the P-channel transistors, which may result in induced performance gain or even in a device degradation, upon further scaling the overall transistor dimensions, for instance in transistors having a gate length of 40 nm and less, as will be described in more detail with reference to FIGS. 1a-1f.

FIG. 1a schematically illustrates a cross-sectional view of a semiconductor device 100 in which a semiconductor layer 102, such as a silicon layer, is formed above a substrate 101, such as a silicon substrate and the like. The semiconductor layer 102 typically comprises a plurality of semiconductor regions or active regions, which are to be understood as semiconductor regions in and above which one or more transistor elements are to be formed. In the example shown, an active region 102A is provided so as to accommodate a plurality of P-channel transistors 150, the performance of which is to be enhanced by incorporating a strain-inducing silicon/germanium alloy, as is also discussed above. In the manufacturing stage shown, the transistors 150 comprise gate electrode structures 160, which may comprise a sophisticated gate dielectric layer 161, in which a high-k dielectric material, for instance in the form of hafnium oxide and the like, may be incorporated. It should be appreciated that the gate dielectric material 161 may also include a conventional dielectric material, for instance in the form of a silicon oxynitride material, however, with a significantly reduced thickness of approximately 1 nm and less so as to provide superior interface characteristics. On the other hand, an additional high-k dielectric material layer may provide the required physical thickness, however, without unduly reducing the overall capacitive coupling. Furthermore, as discussed above, an appropriate metal-containing electrode material 162 may be formed above a gate dielectric material 161, for instance in the form of titanium nitride and the like, wherein specific work function metal species, such as aluminum, may also be incorporated in the layer 162 and/or in the layer 161, depending on the overall process strategy for adjusting the electronic characteristics of the gate electrode structures 160. Moreover, a semiconductor-based electrode material 163, such as an amorphous silicon material and/or a polycrystalline silicon material may be provided above the layer 162, followed by a dielectric cap layer or layer system 164, for instance comprised of silicon nitride, silicon dioxide and the like. Moreover, a reliable confinement of sidewalls of the materials 163, 162, 161 may be accomplished by providing a spacer or liner structure 165, for instance comprised of a silicon nitride material and the like. As discussed above, since the material layers 161 and 162 and the previous processing of the device 100 may substantially determine the resulting threshold voltage, any further exposure to any reactive process atmospheres during the further processing of the device 100 may be suppressed, thereby requiring a reliable confinement by means of the spacer structure 165 during the further processing after patterning the gate electrode structures 160.

Moreover, as also previously explained, in some approaches, a semiconductor alloy 104 is provided on top of the base material of the active region 102A, for instance in the form of a silicon/germanium alloy, in order to appropriately adapt the threshold voltage of the transistors 150. Moreover, in the manufacturing stage shown, cavities 103 are formed in the active region 102A with a desired shape and size so as to form therein a strain-inducing silicon/germanium alloy in a later manufacturing stage.

The semiconductor device 100 as shown in FIG. 1a may be formed on the basis of the following process strategy. The active region 102A may be provided by forming appropriate isolation structures (not shown), thereby laterally delineating the active region 102A so as to have the desired lateral size and shape. Thereafter, appropriate materials are provided for the gate dielectric material 161 and the electrode material 162, wherein it should be appreciated that typically different work function metal species are required for P-channel transistors and N-channel transistors, thereby requiring a corresponding process sequence for selectively positioning appropriate work function metal species in and/or above the gate dielectric material 161 for the transistors 150 on the one hand, and providing an appropriate work function metal species in and/or above the gate dielectric material 161 of N-channel transistors (not shown). If desired, specific thermal treatments may be performed so as to initiate diffusion of work function metal species and provide a thermally stabilized material configuration. Thereafter, the electrode material 163 is deposited, possibly in combination with additional material layers, such as the cap layer system 164, which may then be patterned so as to act as a hard mask in order to finally pattern the gate electrode structures 160, as shown in FIG. 1a, with a gate length in accordance with the overall design rules.

For example, as discussed above, in sophisticated applications, short channel transistors having a gate length, i.e., in FIG. 1a, the horizontal extension of the electrode material 162 of 40 nm and less. Next, the spacer or liner structure 165 may be formed, for instance by low pressure chemical vapor deposition (CVD), multilayer deposition techniques and the like, followed by a subsequent etch process, wherein, in other device areas, an etch mask may be provided so as to preserve corresponding material layers during the further processing for forming the cavities 103 and thereafter in a selective epitaxial growth process for refilling the cavities with a silicon/germanium alloy.

FIG. 1b schematically illustrates the device 100 in an advanced manufacturing stage in which a silicon/germanium alloy 151 is formed in the cavities 103, which is accomplished by applying well-established selective epitaxial growth techniques, in which process parameters are controlled such that a desired germanium concentration and concentration profile is obtained. Generally, increasing the germanium concentration may result in superior strain conditions in the active regions 102A, while, however, maximum germanium concentration may be restricted by the number of lattice defects, which are typically associated when forming a high germanium concentration in the material 151. For example, values of approximately 20-30 atomic percent germanium or higher may be applied when forming the semiconductor material 151 in the cavities 103.

FIG. 1c schematically illustrates the device 100 in a further advanced manufacturing stage in which the dielectric cap layer or cap layer system 164 (FIG. 1b) is removed, which may be accomplished on the basis of wet chemical etch recipes, plasma-assisted etch recipes and the like. Frequently, integrity of the liner or spacer structure 165 is to be preserved, as discussed above, which may be accomplished by providing sacrificial spacer elements (not shown), for instance comprised of silicon dioxide, thereby enabling a selective removal of the dielectric cap layer while substantially preserving the spacer structure 165. It turns out, however, that during the complex sequence of providing sacrificial spacer elements and finally removing the dielectric cap layer, also a pronounced degree of material erosion may occur in the exposed portions of the active region 102A. That is, a significant part of the material 151 is removed, thereby forming a recess 104R.

FIG. 1d schematically illustrates the device 100 in a further advanced manufacturing stage in which implantation processes 105 are applied in order to incorporate drain and source dopant species so as to form drain and source extension regions 152E with a desired high concentration and a very shallow depth profile, as is also discussed above. Furthermore, a further implantation process 106 may be performed so as to incorporate counter-doping species in order to locally increase the overall well dopant concentration in the active region 102A, indicated as halo regions 153. As discussed above, corresponding sophisticated dopant profiles may be required for adjusting the overall transistor characteristics, such as threshold voltage, separation current, off current and the like.

FIG. 1e schematically illustrates the device 100 in a further advanced manufacturing stage. As shown, an additional spacer structure 166 may be formed in the gate electrode structures 160, thereby requiring additional deposition, etch and cleaning steps, which may contribute to a further material erosion, thereby increasing the recess 104R. Furthermore, in this manufacturing stage, drain and source regions 152 may be formed in the active regions 102A and may appropriately connect to the previously formed drain and source extension regions 152E, which may be accomplished by sophisticated implantation techniques. Thereafter, any anneal processes may be performed in order to establish the final dopant profile of the drain and source regions 152 in combination with the previously implemented halo regions (not shown).

It turns out, however, that the complex interaction of the various process steps, and in particular the significant loss of material of the strain-inducing silicon/germanium alloy 151, may result in a reduced performance gain or even in a performance degradation for devices having a channel length of 40 nm and less since, for example, the strain 154S in a channel region 154 may be significantly reduced due to the pronounced degree of recessing 104R.

Consequently, in some approaches, it has been proposed to compensate for the significant material loss by forming the strain-inducing material 151 with an increased fill height.

FIG. 1f schematically illustrates the semiconductor device 100 in a manufacturing stage after the deposition of the strain-inducing silicon/germanium alloy 151 with an extra fill height so as to compensate for the expected material loss, as indicated by 104R. It turns out, however, that significant transistor deterioration is observed which is believed to be caused by an inappropriate profile of the drain and source extension regions 152E (FIG. 1e) and possibly of any halo regions since in particular the drain and source regions 152E may not appropriately connect to any deep drain and source areas, which have to be formed in a later manufacturing stage in order to complete the drain and source regions. Consequently, the approach of providing an initially increased fill height is less than desirable, unless significant efforts are made in performing any additional implantation processes, thereby requiring additional lithography steps which in turn may even further contribute to an overall material loss.

In view of the situation described above, the present disclosure relates to manufacturing techniques and semiconductor devices in which sophisticated high-k metal gate electrode structures may be formed in combination with embedded semiconductor materials, such as strain-inducing semiconductor materials, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which sophisticated high-k metal gate electrode structures may be provided in an early manufacturing stage in combination with embedded semiconductor materials, for instance used for inducing strain and the like, wherein, nevertheless, a desired complex dopant profile of the drain and source regions may be achieved without unduly contributing to the overall process complexity. To this end, a first portion of a semiconductor material to be formed in cavities of the active regions may be deposited with a desired material composition and up to a desired fill height so as to enable the subsequent incorporation of the drain and source species and, if required, of any counter-doping species, in order to establish a desired profile for drain and source extension regions. Thereafter, a further growth process may be performed so as to provide additional semiconductor material, such as a strain-inducing material, or any other appropriate semiconductor material in order to compensate for a possible material loss during the further processing. Since drain and source extension regions, and possibly the halo regions, are already appropriately positioned within the active region, an appropriate connection of the drain and source extension regions to any deep drain and source areas to be provided in a later manufacturing stage may be guaranteed without requiring any additional sophisticated implantation steps. In some illustrative aspects disclosed herein, the implantation process or process sequence for incorporating the drain and source extension regions and possibly the halo regions may be performed in the presence of a hard mask that may cover the transistors, such as N-channel transistors, thereby reducing the number of required lithography steps.

One illustrative method disclosed herein relates to forming a transistor. The method comprises performing a first epitaxial growth process so as to form a first semiconductor material in cavities that are formed in an active region. The method further comprises forming drain and source extension regions in the active region in the presence of a gate electrode structure, wherein the active region comprises the first semiconductor material. The method additionally comprises performing a second epitaxial growth process so as to form a second semiconductor material above the first semiconductor material. Additionally, the method comprises forming drain and source regions in the active region by forming deep drain and source areas so as to connect to the drain and source extension regions.

A further illustrative method disclosed herein comprises forming a first gate electrode structure on a first active region and a second gate electrode structure on a second active region. The method further comprises forming a first semiconductor material in cavities that are formed in the first active region, while the second active region and the second gate electrode structure are covered with a hard mask. Furthermore, the method comprises forming drain and source extension regions in the first active region after forming the first semiconductor material. Additionally, the method comprises forming a second semiconductor material above the first semiconductor material after forming the drain and source extension regions in the first active region.

One illustrative semiconductor device disclosed herein comprises an active region that is formed above a substrate. Moreover, the semiconductor device comprises a gate electrode structure formed on the active region and comprising a gate dielectric material including a high-k dielectric material, a metal-containing cap material formed on the gate dielectric material and a semiconductor electrode material. Furthermore, the semiconductor device comprises a first semiconductor material formed in cavities of the active region, wherein the first semiconductor material induces strain in a channel region of the active region. Furthermore, the semiconductor device comprises drain and source extension regions formed in the active region and in a portion of the first semiconductor material. Additionally, the semiconductor device comprises second semiconductor material formed on the first semiconductor material, wherein the first and second semiconductor materials form an interface.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1e schematically illustrate cross-sectional views of a semiconductor device during various manufacturing stages in forming a strain-inducing semiconductor material in combination with a high-k metal gate electrode structure for sophisticated P-channel transistors, according to conventional strategies;

FIG. 1f schematically illustrates a conventional approach for compensating for a material loss of the silicon/germanium by providing an extra height upon depositing the silicon/germanium alloy;

FIGS. 2a-2e schematically illustrate cross-sectional views of a semiconductor device during various manufacturing stages in incorporating a semiconductor material, such as a strain-inducing semiconductor material, with an extra height so as to compensate for a material loss during the further processing, wherein a second epitaxial growth process may be applied, according to illustrative embodiments; and

FIGS. 2f-2g schematically illustrate cross-sectional views of the semiconductor device according to further illustrative embodiments in which the deposition of a second portion of a semiconductor material may be applied to transistors of different conductivity type.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure addresses the problem of performance degradation or reduced performance gain in sophisticated semiconductor devices in which transistors having a gate length of 50 nm and less may be provided on the basis of sophisticated high-k metal gate electrode structures, which are formed in an early manufacturing stage in combination with performance enhancing mechanisms, in which semiconductor material is to be embedded into the active region of at least some transistors by selective epitaxial growth techniques. To this end, the material loss during the complex manufacturing process in the active regions may be compensated for, at least for some of the transistors, by providing a first portion of the embedded semiconductor material, for instance in the form of a strain-inducing semiconductor material, with a desired height so as to comply with subsequent implantation processes for forming drain and source extension regions, wherein any appropriate extra height may be provided by performing an additional selective epitaxial growth process, in which any desired height level may be adjusted in view of the further processing.

In some illustrative embodiments disclosed herein, the first epitaxial growth process may be performed on the basis of a hard mask, which may cover other transistor areas, wherein the hard mask may also be used as an implantation mask and a deposition mask for forming a second portion of the semiconductor material to be selectively provided in the non-covered transistor areas. In other illustrative embodiments, the second epitaxial growth process may be performed for transistors which may have received the first portion of the semiconductor material, and for transistors which may not have received the first portion, in order to also compensate for a material loss in any of these transistors during the further processing. In this case, the second portion of the semiconductor material may be provided so as to not unduly affect performance of any of these transistors.

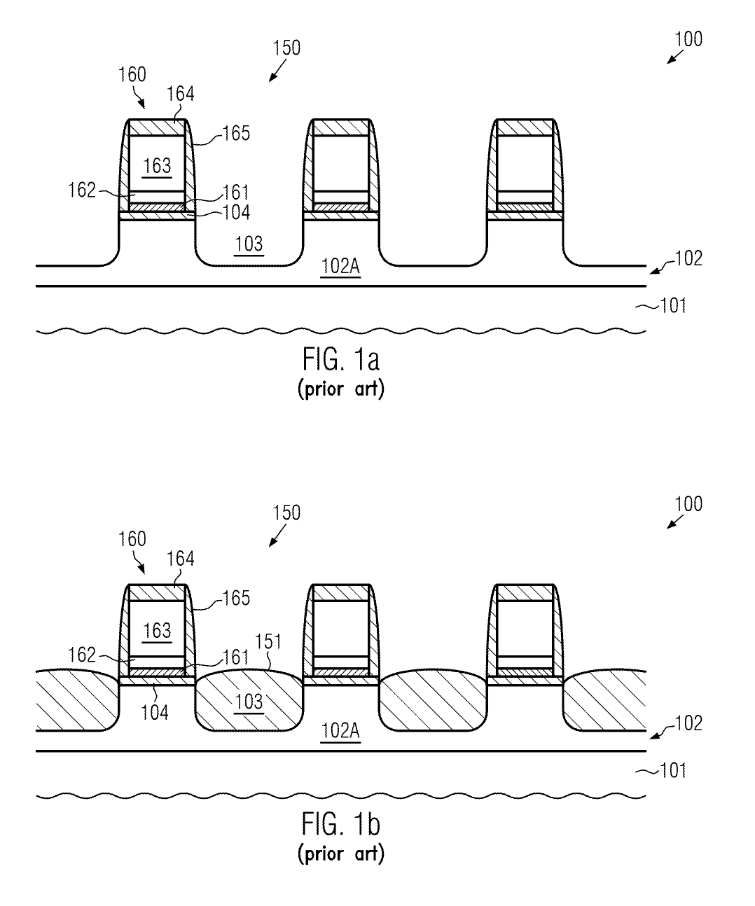

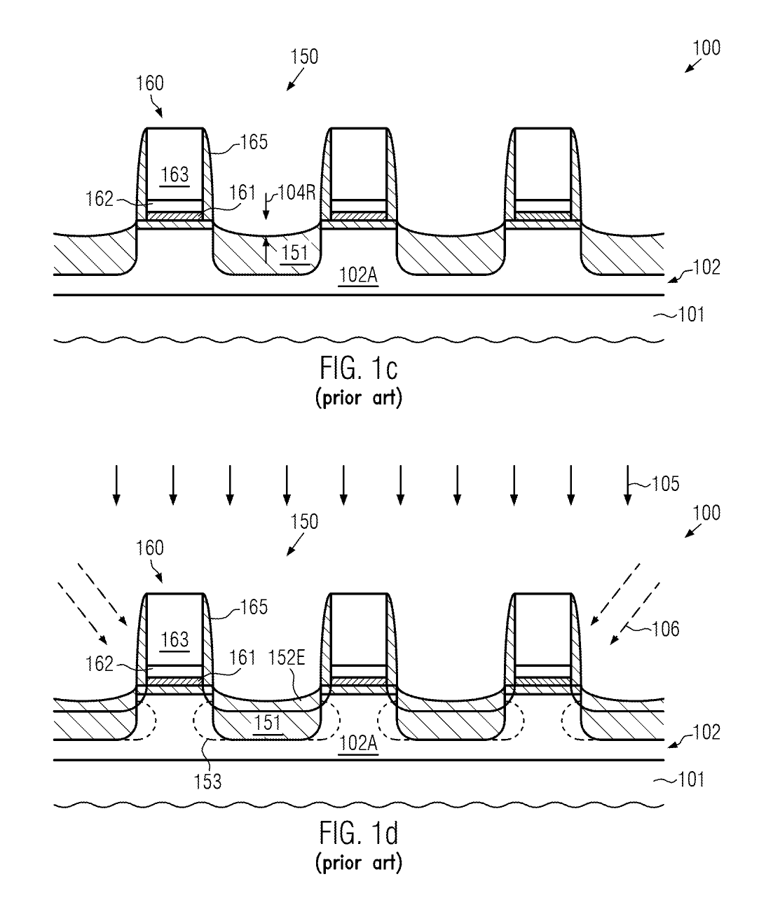

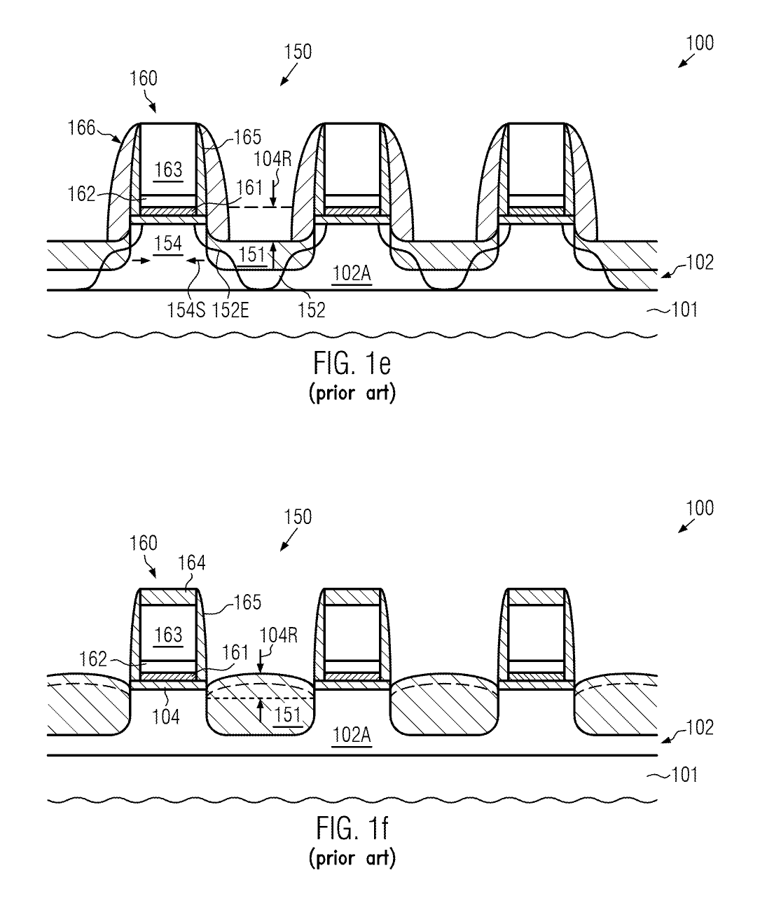

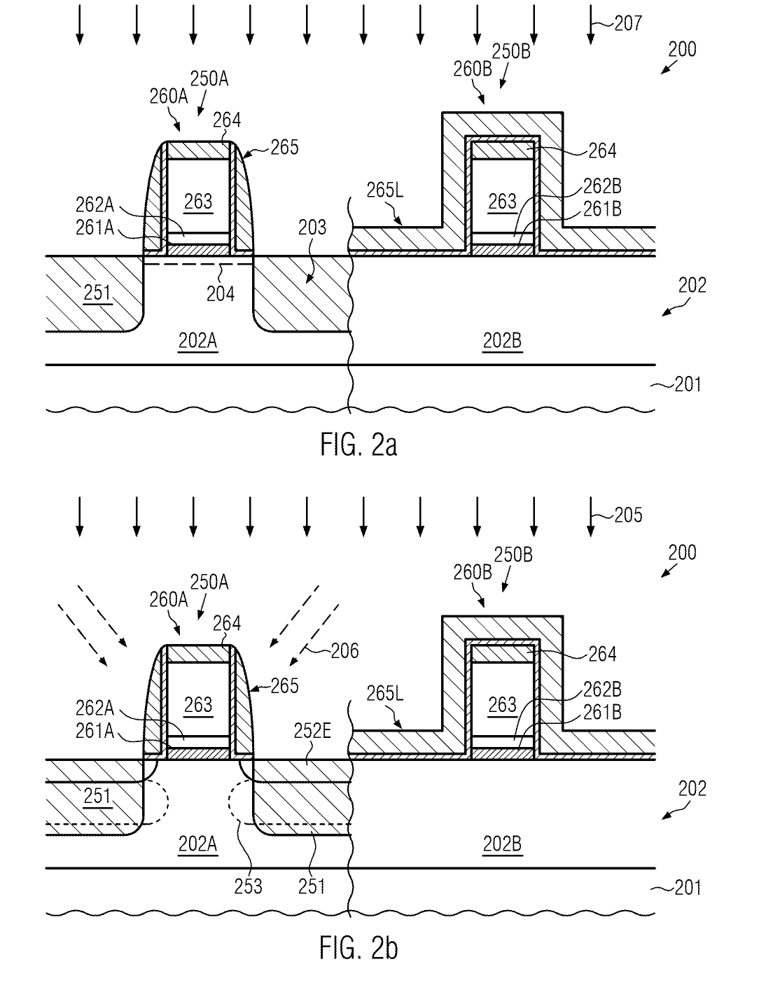

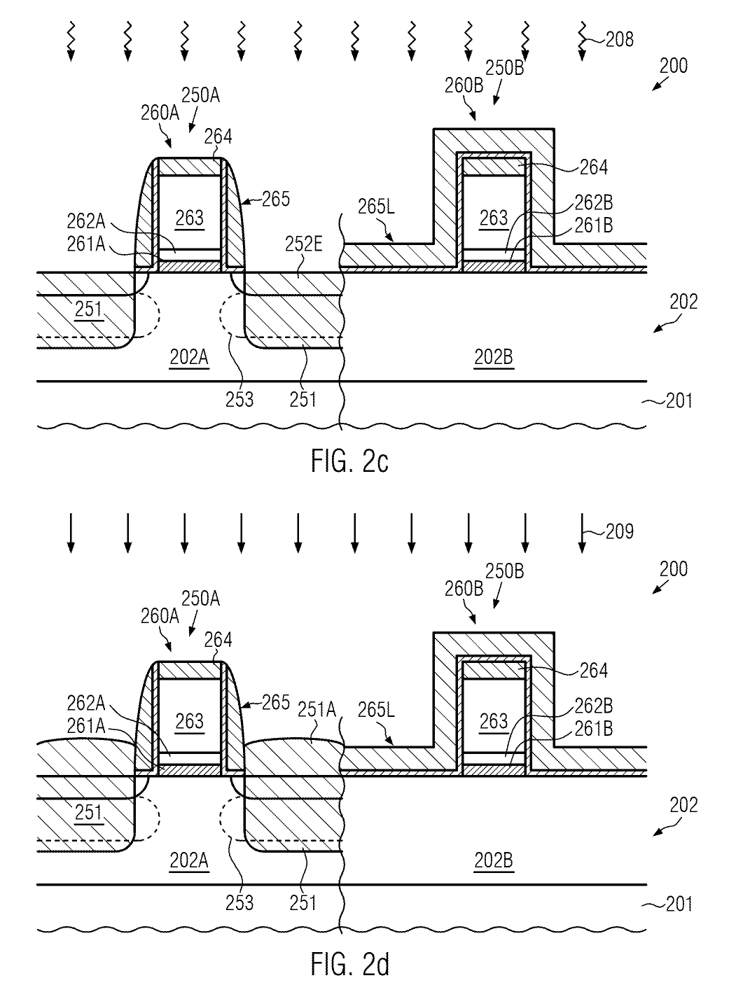

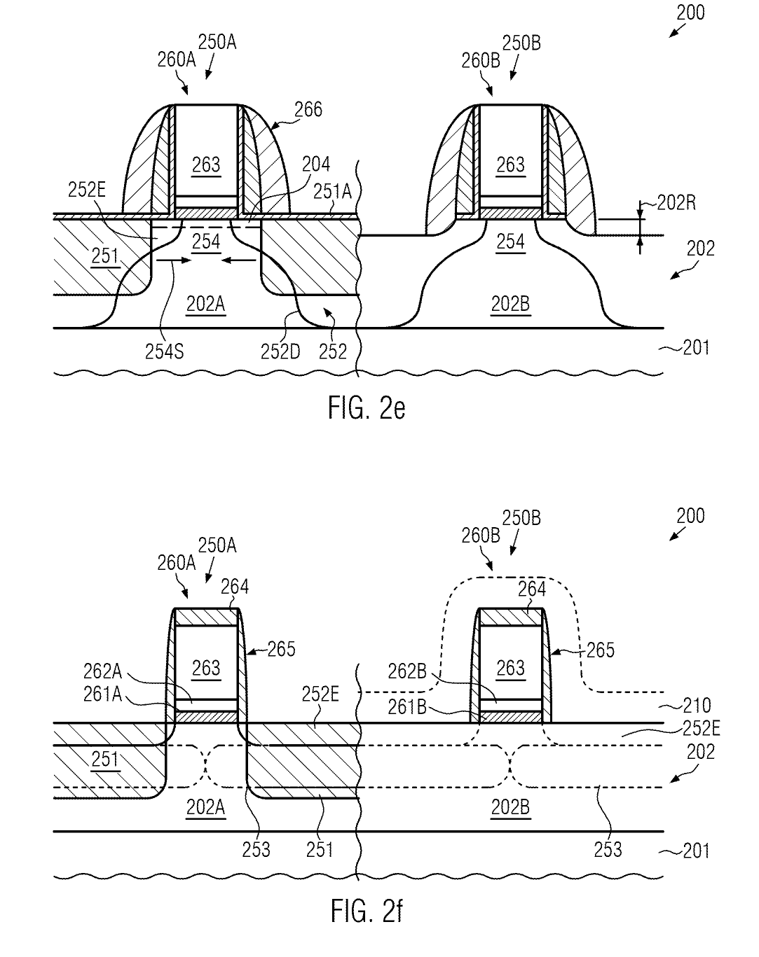

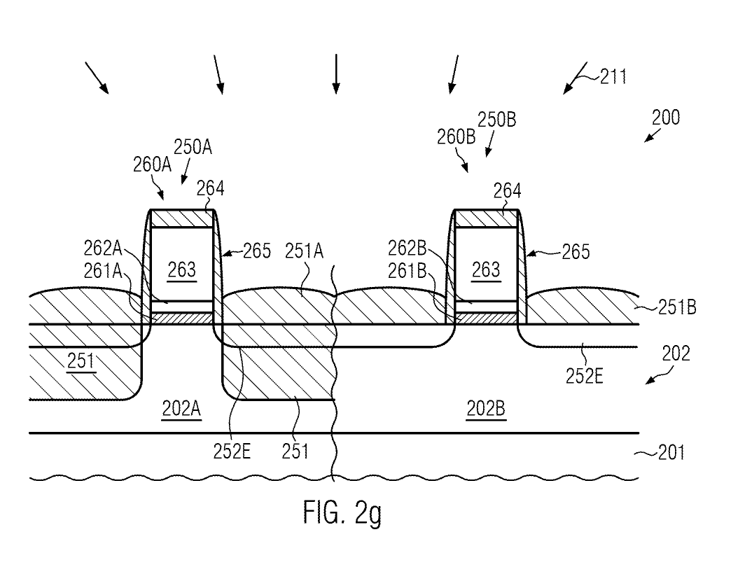

With reference to FIGS. 2a-2g, further illustrative embodiments will now be described in more detail, wherein reference may also be made to FIGS. 1a-1f, if appropriate.

FIG. 2a schematically illustrates a cross-sectional view of a semiconductor device 200 comprising a substrate 201 and a semiconductor layer 202. The semiconductor layer 202 may comprise a plurality of semiconductor regions or active regions, wherein, for convenience, a first active region 202A and a second active region 202B are illustrated in FIG. 2a. The first active region 202A may correspond to a first transistor 250A, which may receive an embedded semiconductor material 251 formed in cavities 203 so as to enhance performance of the transistor 250A. On the other hand, the second active region 202B may correspond to a second transistor 250B, which may not require an embedded semiconductor material. As shown, the transistor 250A may comprise a gate electrode structure 260A, which in turn may comprise a gate dielectric layer 261A, followed by an electrode material 262A. As previously explained with reference to the semiconductor device 100, in sophisticated applications, the gate dielectric layer 261A may comprise a high-k dielectric material and the electrode material 262A may have an appropriate function, for instance adjusted on the basis of an appropriate work function metal species. Furthermore, a semiconductor-based electrode material 263 may be provided in combination with a dielectric cap layer or cap layer system 264. Furthermore, the materials 263, 262A, 261A may be confined by a sidewall liner or spacer structure 265. Moreover, an additional threshold adjusting semiconductor alloy 204 may be provided so as to obtain a desired threshold voltage. The transistor 250B may comprise a gate electrode structure 260B including a gate dielectric layer 261B in combination with an electrode material 262B and the semiconductor-based electrode material 263, followed by the dielectric cap layer 264. As also explained above with reference to the semiconductor device 100, the dielectric material 261B, which may comprise a high-k dielectric component, may also include metal species for adjusting the overall electronic characteristics and/or any such work function adjusting metal species may be incorporated in the layer 262B. Furthermore, a corresponding liner or spacer (not shown) may be formed on sidewalls of the gate electrode structure 260B, while, in the embodiment shown, liner materials 265L may not yet be patterned into a corresponding spacer structure, such as the spacer structure 265 of the first gate electrode structure 260A.

It should further be appreciated that, with respect to the transistors 250A, 250B and the corresponding gate electrode structures 260A, 260B, the same criteria may apply as previously explained with reference to the semiconductor device 100. In particular, the length of the gate electrode structures 260A, 260B may be 40 nm and less in sophisticated applications.

The semiconductor device 200 as illustrated in FIG. 2a may be formed on the basis of any appropriate process strategy, for instance based on processes as are also described above with reference to the semiconductor device 100. For example, after appropriately delineating the active regions 202A, 202B by providing respective isolation structures (not shown), the gate electrode structures 260A, 260B may be formed in accordance with patterning strategies as also described above. Thereafter, an appropriate liner material, such as the liner 265L, may be provided and may be selectively patterned into the structure 265 by applying any appropriate etch techniques in combination with an etch mask, such as a resist mask (not shown), so as to cover the gate electrode structure 260B and the active region 202B. In the corresponding patterning process, also the cavities 203 may be formed in the active region 202A so as to have a desired size and shape. Moreover, as also discussed with reference to the device 100, if required, the channel semiconductor alloy 204 may be formed prior to forming the gate electrode structures 260A, 260B. Next, a first epitaxial growth process 207 may be performed so as to fill the cavities 203 with a semiconductor material 251 having appropriate material characteristics in accordance with requirements of the transistor 250A. For example, the material 251 may be provided as a strain-inducing semiconductor alloy so as to induce a desired type of strain in the active region 202A. For example, silicon/germanium, silicon/germanium/tin and the like may be formed on a silicon base material, thereby inducing a compressive strain in the active region 202A. In other cases, a silicon/carbon material may be provided so as to induce a tensile strain. It should further be appreciated that the material 251 may be provided with varying material characteristics, for instance in terms of the concentration of the alloy-forming species, the degree of in situ doping and the like. Furthermore, the material 251 may be formed during the process 207 so as to extend to a desired height level, for instance to a height level that is substantially defined by the gate dielectric layer 261A. By appropriately adjusting the height level of the material 251, the desired superior conditions for incorporating drain and source dopant species or halo dopant species may be achieved during the further processing. It should be appreciated that the deposition process 207 may be performed on the basis of any well-established process recipes, wherein the dielectric cap layer 264 in combination with the spacer structure 265 may reliably confine the sensitive materials 261A, 262A while the active region 202B and the gate electrode structure 260B are masked by the layer 265L, which may thus act as a hard mask material, at least during the deposition process 207.

FIG. 2b schematically illustrates the semiconductor device 200 in a further advanced manufacturing stage. As illustrated, an implantation process 205 may be performed so as to incorporate a dopant species for forming drain and source extension regions 252E in the first active region 202A. In the embodiment shown, the implantation process 205 may be performed in the presence of the mask layer 265L, which may reliably block the implantation species from penetrating the active region 202B and the gate electrode structure 260B. In other cases, if required, an additional resist mask may be provided if the thickness of the layer 265L is considered inappropriate for the implantation process 205. In other illustrative embodiments, a further implantation process 206 may be performed so as to incorporate a counter-doping species with respect to the extension regions 252E in order to locally increase the well dopant concentration. For example, corresponding halo regions 253 may be formed, if considered necessary for adjusting the overall characteristics of the transistor 250A. Also in this case, the layer 265L may act as an efficient implantation mask.

FIG. 2c schematically illustrates the device 200 according to some illustrative embodiments in which an anneal process 208 may be performed so as to activate the dopant species of the regions 252E and possibly of the halo regions 253, if provided, while at the same time also reducing implantation-induced damage. The anneal process 208 may be performed on the basis of sophisticated anneal techniques, such as laser-based anneal processes, flashlight-based anneal processes and the like, while in other cases rapid thermal anneal (RTA) process techniques may be applied, depending on the desired degree of dopant diffusion and the like.

FIG. 2d schematically illustrates the semiconductor device 200 in a further advanced manufacturing stage. As shown, the device 200 is exposed to a further deposition atmosphere 209 in order to form a second semiconductor material 251A on the first semiconductor material 251. The deposition process 209 may be performed as a selective epitaxial growth process so as to use the cap layer 264 and the spacer structure 265 and the hard mask layer 265L as efficient deposition masks. During the deposition process 209, appropriate material characteristics of the semiconductor material 251A may be adjusted by correspondingly controlling the process parameters. For example, the material 251A may be provided as a strain-inducing alloy, at least partially, so as to enhance the overall strain efficiency, even after the removal of a significant portion of the second semiconductor material 251A. In other cases, the material 251A may be provided with a varying material composition so as to comply with performance requirements and also provide superior conditions during the further processing. To this end, at least a portion of the material 251A may be provided in the form of a silicon material, if considered appropriate for the further processing. Moreover, the height level of the second semiconductor material 251A may be selected so as to compensate for certain material erosion during the further processing in order to obtain a desired final height level of the active region 202A after completing the basic configuration of the transistors 250A, 250B. Since a corresponding material loss may be readily determined by experiments of conventional process strategies, an appropriate initial height of the second portion 251A in combination with the previously provided material 251 may be readily determined. Thereafter, the further processing may be continued by removing the layer 265L, for instance when an appropriate protective liner material may still be present on sidewalls of the gate electrode structure 260B, while in other cases the layer 265L may be patterned into a spacer structure, such as the spacer structure 265 of the first gate electrode structure 260A. In this case, the resulting spacer structure may also be efficiently used as an offset spacer for forming drain and source extension regions in the second active region 202B. Moreover, at any appropriate stage, the dielectric cap layers 264 may be removed, for instance possibly on the basis of a sacrificial sidewall spacer in order to preserve the reliable confinement of the sensitive materials 261A, 262A, 261B, 262B, as is also previously explained. Moreover, any material loss associated with these processes may consume a part of the material 251A, however, without causing a pronounced degree of recessing, as is the case in conventional process strategies.

FIG. 2e schematically illustrates the device 200 in a further advanced manufacturing stage. As shown, the gate electrode structures 260A, 260B may comprise an additional spacer structure 266, which may be used to incorporate further drain and source dopant species in order to form deep drain and source areas 252D. As discussed above, the preceding manufacturing flow may cause a significant material loss, which may thus result in a significantly reduced height of the second semiconductor material 251A, however without causing a significant loss of dopants of the previously formed drain and source extension regions 252E. Moreover, as discussed above, the initial height of the material 251A may be appropriately selected so as to not unduly recess the first semiconductor material 251, while in other cases, as shown, even a certain extra height may be preserved, if considered appropriate for the overall characteristics of the transistor 250A. It should be appreciated that the deep drain and source regions 252D may be obtained on the basis of well-established implantation techniques by using the spacer structure 266, wherein, due to the appropriately positioned extension regions 252E, an appropriate connection may be achieved between the regions 252E and the deep drain and source areas 252D, thereby forming the desired drain and source regions 252. Consequently, the material 251, possibly in combination with the residue of the material 251A, may provide desired transistor performance, for instance in terms of a desired high strain 254S, which may be induced in a channel region 254 of the transistor 250A.

Similarly, the transistor 250B may have formed therein drain and source regions 252, wherein also a certain degree of recessing 202R may have been generated during the previous processing, which, however, may have a lesser effect on the overall transistor performance since, for instance, any embedded semiconductor material may not be provided in the active region 202B, which in the case of the transistor 250A may have a significant influence on the overall transistor behavior.

FIG. 2f schematically illustrates the semiconductor device 200 according to further illustrative embodiments in which the first semiconductor material 251 may be selectively formed in the transistor 250A, which may be accomplished on the basis of process techniques as described above. Moreover, the drain and source extension regions 252E may be provided in the transistor 250A, possibly in combination with the halo region 253, if required. In the manufacturing stage shown, the gate electrode structures 260A, 260B may have substantially the same configuration with respect to the spacer structure 265 and the cap layer 264. Moreover, in some embodiments, extension regions 252E and/or halo regions 253 may also be formed in the active region 202B.

The semiconductor device 200 as shown in FIG. 2f may be formed on the basis of the process strategies as described above for incorporating the material 251 selectively in the active region 202A. Prior to the incorporation of the material 251, however, the spacer structure 265 may be formed in the gate electrode structure 260B, possibly together with the spacer structure 265 in the gate electrode structure 260A, and thereafter an appropriate hard mask layer 210 may be formed, for instance, on the basis of an oxide material, a silicon nitride material and the like, which may be selectively removed from above the first active region 202A. Hence, the hard mask layer 210 may act as an efficient deposition mask during the corresponding selective epitaxial growth process. Thereafter, the extension regions 252E, possibly in combination with the halo regions 253, may be formed by applying an appropriate masking regime, wherein, prior to forming the extension regions 252E and halo regions 253 in the second active region 202B, the hard mask 210 may be removed. It should be appreciated that, in some illustrative embodiments, the hard mask 210 may act as an implantation mask for incorporating the dopant species into the active region 202A, as is also described above with reference to FIG. 2a, thereby reducing the number of required lithography steps.

FIG. 2g schematically illustrates the semiconductor device 200 during a further selective epitaxial growth process 211, in which the second portion 251A may be formed above the active region 202A, while a semiconductor material 251B may be formed above the active region 202B, wherein the materials 251A, 251B may have any appropriate composition so as to efficiently compensate for any material loss in both active regions 202A, 202B during the further processing, while not negatively affecting the overall transistor characteristics. For example, at least a significant portion of the material 251A, 251B may be provided in the form of a silicon material, thereby providing similar process conditions for both transistors 250A, 250B, without inducing a non-desired strain in the active region 202B. In other cases, at least at an initial phase of the deposition process 211, a strain-inducing material may be deposited, which may have a strain component that is advantageous for the transistor 250A, while a corresponding strain component may be relaxed to a pronounced degree in the transistor 250B during the formation of the deep drain and source areas for the transistor 250B when incorporating heavy dopant species.

Consequently, after the deposition of the materials 251A, 251B, the further processing may be continued by removing the cap layers 264, for instance on the basis of a sacrificial spacer (not shown), wherein an associated material loss may be efficiently compensated for by the materials 251A, 251B. Hence, superior surface topography and thus transistor performance and uniformity may be accomplished for both the transistor 250A and the transistor 250B.

As a result, the present disclosure provides manufacturing techniques and semiconductor devices in which the material loss of an embedded semiconductor material, such as a strain-inducing semiconductor material, may be efficiently compensated for by applying a second epitaxial growth after incorporating the dopant species for the drain and source extension regions in order to provide the required complex dopant profile of the drain and source regions. Hence, superior performance may be achieved, for instance by enhancing the overall strain effect, without degrading the complex dopant profile of the drain and source regions.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a transistor, the method comprising:
performing a first epitaxial growth process so as to form a first semiconductor material in cavities formed in an active region;
forming drain and source extension regions in said active region in the presence of a gate electrode structure, said active region comprising said first semiconductor material;
performing a second epitaxial growth process so as to form a second semiconductor material above said first semiconductor material; and
forming drain and source regions in said active region by forming deep drain and source areas so as to connect to said drain and source extension regions.

2. The method of claim 1, wherein at least one of said first and second semiconductor materials is formed so as to induce a strain in a channel region of said active region.

3. The method of claim 1, wherein performing said first epitaxial growth process comprises controlling a fill height in said cavities so as to be equal to or less than a height level of a gate insulation layer of said gate electrode structure.

4. The method of claim 1, further comprising forming said gate electrode structure by implementing a high-k dielectric material into a gate insulation layer of said gate electrode structure.

5. The method of claim 4, further comprising forming a threshold adjusting semiconductor material on said active region prior to forming said gate electrode structure.

6. The method of claim 1, further comprising performing an implantation process so as to introduce a counter-doping species into said active region prior to performing said second epitaxial growth process.

7. The method of claim 1, wherein forming said drain and source extension regions comprises using a P-type dopant species.

8. The method of claim 5, wherein said threshold adjusting semiconductor material is comprised of silicon and germanium.

9. The method of claim 1, wherein at least one of said first and second semiconductor materials is comprised of silicon and germanium.

10. The method of claim 1, further comprising forming a hard mask above a second active region and a second gate electrode structure formed on said second active region and performing at least said first epitaxial growth process in the presence of said hard mask.

11. The method of claim 10, wherein forming said drain and source extension regions in said active region comprises using said hard mask as an implantation mask for said second active region.

12. The method of claim 10, wherein performing said second epitaxial growth process comprises using said hard mask as a growth mask so as to suppress material deposition above said second active region.

13. A method, comprising:
forming a first gate electrode structure on a first active region and a second gate electrode structure on a second active region;
forming a first semiconductor material in cavities formed in said first active region while covering said second active region and said second gate electrode with a hard mask;
forming drain and source extension regions in said first active region after forming said first semiconductor material; and
forming a second semiconductor material above said first semiconductor material after forming said drain and source extension regions in said first active region.

14. The method of claim 13, wherein said second semiconductor material is formed by using said hard mask as a deposition mask.

15. The method of claim 13, wherein forming said second semiconductor material comprises forming said second semiconductor material on said active region.

16. The method of claim 13, wherein said first gate electrode structure is formed so as to include a first work function metal species and said second electrode structure is formed so as to include a second work function metal species that differs from said first work function metal species.

17. The method of claim 13, further comprising performing a halo implantation process prior to forming said second semiconductor material.

18. The method of claim 13, wherein said first semiconductor material is formed so as to induce strain in a channel region of said first active region.

19. A semiconductor device, comprising:
an active region formed above a substrate;
a gate electrode structure formed on said active region, said gate electrode structure comprising a gate dielectric material including a high-k dielectric material, a metal-containing cap material formed on said gate dielectric material and a semiconductor electrode material;
a first semiconductor material formed in cavities of said active region, said first semiconductor material inducing strain in a channel region of said active region;
drain and source extension regions formed in said active region and in a portion of said first semiconductor material; and
a second semiconductor material formed on said first semiconductor material and forming an interface therewith.

20. The semiconductor device of claim 19, wherein a length of said gate electrode structure is 40 nm or less.
